(19) United States
(12) Patent Application Publication
(10) Pub. No.: US 2005/0025959 A1
(43) Pub. Date: Feb. 3, 2005

(54) Hard pellicle and fabrication thereof

(76) Inventor: Robert A. Bellman, Painted Post, NY (US)

Correspondence Address: CORNING INCORPORATED, SP-TI-3-1, CORNING, NY, 14831, US

(21) Appl. No.: 10/632,363

(22) Filed: Jul. 31, 2003

(51) Int. Cl. B32B 9/04; C23C 14/00

(52) U.S. Cl. 428/336; 428/446; 428/696; 427/523; 427/569

(57) ABSTRACT

Disclosed are thin hard pellicle for projection photolithography and process for making the same. The thin hard pellicle comprises a pellicle layer having a thickness in the range of about 5 to 120 μm and a mount frame attached to the peripheral area of a surface of the pellicle layer. The pellicle layer can consist essentially of a material selected from silica, fluorine doped silica, aluminum doped silica, methylated silica, fluorinated and methylated silica, fluorinated aluminum doped silica, CaF₂, MgF₂, BaF₂ and SiC. The mount frame is preferred to have substantially the same CTE of the pellicle layer to minimize stress caused by temperature change. The process for making the hard pellicle involves ion implantation of a silicon wafer, deposition of the pellicle layer on the silicon wafer, mounting the frame to the pellicle layer and the separation of the pellicle from the wafer by heat treatment.

### FIELD OF THE INVENTION

The present invention relates to hard pellicles for photomasks and fabrication thereof. In particular, the present invention relates to thin hard pellicles for photomasks used for photolithography at 193 nm and shorter wavelength, and a method for making the same.

### BACKGROUND OF THE INVENTION

Photomask handling is significantly more challenging for photolithography at wavelengths shorter than 193 nm, such as 157 nm, than for any previous generation of optical lithography. One of the greatest concerns is the solution for pellicle, which is the cover used to protect the reticle during the lithographic process.

Soft polymeric pellicle materials good at 193 nm, such as fluorine polymers have been shown to have good transmission initially but soon degraded because of photochemical darkening when used at 157 nm. This is because the chemical bonds in the polymer absorbs the high-energy 157 nm photons and begin to break. Transmission degrades to an unacceptable level due to the darkening and ultimately the pellicles themselves often burst. Although initial transmission at 157 nm polymer pellicle samples has steadily increased since early 2000 to a maximum of about 95% as of 2001, it is generally agreed that transmission higher than 99% will be required to reach the necessary laser lifetime and durability targets as demanded by the industry. Current laser lifetime requirements for a polymeric pellicle are in the 10 kJ/cm² range with a transmission change of less than 1%. However, the polymer materials available can only reach 7 mJ/cm² range before they have lost up to 45% of their transmission. When the dose is increased to 600 J/cm², there is a total loss of transmission. The lack of laser durability of the polymer materials renders it difficult to find a polymer pellicle solution.

Since there is no polymeric pellicle solution that meets the requirements for transmission, lifetime or durability at 157 nm lithography, the concept of using a hard pellicle has gained popularity. It has been contemplated that by using the same modified fused silica that is used for reticle substrates, a workable pellicle may be produced to meet the durability requirements. A hard pellicle proposed in the industry has a thickness of about 800 nm.

Because of its very thin thickness, soft polymer pellicles do not function as a significant optical element in the exposure tools. However, a silica pellicle having a thickness of 800 nm will function as an optical element in the beam path. As a result, tighter specifications for scratches, localized defects, angle, tilt and bending are required for these hard pellicles. Even if all of these requirements are met, there remains a problem of attaching the pellicles to the frame. A first issue about the frame is flatness. Frame flatness is not an issue with soft polymer pellicle as long as it does not adversely affect the flatness of the reticle. Since the thick hard pellicle functions as an optical element, it is important that the frame flatness must be sufficient not to cause significant distortions of the pellicle layer.

Match of the thermal expansion coefficient of the pellicle layer and the frame is also a factor that needs to be considered with regard to pellicle layer distortion. Since the thermal expansion coefficient for aluminum used currently in frames and the modified fused silica as a hard pellicle film are different, changes in temperature can cause distortions to the pellicle layer. In addition, the adhesives for bonding the frame to the reticle and the pellicle layer to the frame, which were conventionally ignored as long as they do not degrade or contaminate the reticle, need be considered as well. Research has shown that the mechanical properties of these materials can have a significant impact on reticle and pellicle flatness with temperature changes because dissimilar materials are bonded together. While most clean rooms are kept at a controlled temperature, there is no standard for clean room temperature, and no guarantee that the temperature will be the same from the point of manufacture to the point of use. Furthermore, temperature changes of less than a degree have been shown to have several micron impact on reticle and pellicle flatness.

A few other issues relating to this thick hard pellicle for 157 nm and shorter wavelength have never been addressed in the pellicle industry before. Specifically, tilt and uniformity have become critical considerations for the 800 μm pellicle. Therefore, new methods have to be developed for mounting the pellicle to ensure that the pellicle is parallel to the reticle. Unlike soft polymer pellicles, hard pellicles do not allow for gas transfer across the pellicle layer surface. Thus, purging has become more of a problem to hard pellicles. Since the thick hard pellicles constitute an optical element in the light path, its oscillation during purging is especially a problem. The most severe problem associated with the thick hard pellicle, though, is the inspection of the reticles with these new pellicles. Inspection systems will need be designed and built to be specific to this technology while at the same time compatible with previous technology, which entails additional engineering and cost, in order that they can be used for inspecting reticles without a pellicle, or with various types of pellicle, including polymeric pellicles.

U.S. Pat. No. 5,475,575B1 to Ikuta et al. (hereinafter Ikuta et al.) discloses a hard pellicle having a synthetic quartz pellicle layer and a method for making such pellicle. The pellicle layer is required to have less than 100 ppm of OH concentration and to be substantially free of oxygen deficient defect. The specification to meet the requirement of transmission and wavefront distortion with respect to thickness uniformity and sag are difficult to meet. Also, the method disclosed in Ikuta et al. involves forming a discrete sheet of pellicle layer by, for example, thinning and polishing of a fused silica body, followed by cutting and mounting of the pellicle layer to a pellicle mount frame. Making a complete pellicle comprising a thin pellicle layer having a thickness lower than 120 μm mounted to a frame is not practical using the method of Ikuta et al.

The option of not using a pellicle is not acceptable in most cases, as the reticles used in many processes are very costly to maintain without the protection of a pellicle.

The drawbacks of the above thick hard pellicles can be addressed by a thinner hard pellicle with sufficient structural stability. Since optical aberrations scale directly with the pellicle layer thickness, specification constraints will be two orders of magnitude tighter for an 800-μm hard pellicle compared with an 8 μm hard pellicle.

However, the production of a thin hard pellicle less than 120 μm is not without difficulty. The production of the pellicle thin layer and mounting thereof to a frame both constitute great challenges in the prior art. Therefore, there remains a genuine need for a process of making thin hard pellicles with a thickness of less than about 120 nm. There also remains a genuine need for a thin hard pellicle having a thickness lower than 120 μm and good transmission and laser durability at 157 nm and shorter wavelength.

The present invention satisfies these needs.

### SUMMARY OF THE INVENTION

Accordingly, in a first aspect, the present invention provides a process for making a thin hard pellicle for a photomask, comprising the following steps:
(i) providing a silicon wafer having a substantially flat surface;
(ii) forming an ion-implanted layer adjacent to the flat surface of the silicon wafer;
(iii) depositing a pellicle layer having a first surface and a second surface on the surface of the ion-implanted layer, with the first surface bonding to the surface of the ion-implanted layer, and the second surface opposite to the first surface;
(iv) bonding a pellicle mount frame to the second surface of the pellicle layer; and
(v) separating the pellicle layer and a portion of the ion-implanted layer from the silicon wafer at a location within the ion-implanted layer by heat treatment.

According to a preferred embodiment of the present invention process, in step (ii) the ion-implanted layer is formed by H, He and/or F ion implantation; and in step (v), the pellicle layer is separated from the wafer by annealing at a temperature for an amount of time sufficient to effect the separation of the pellicle layer. Steps (iv) and (v) may be carried out simultaneously. According to a preferred embodiment of the present invention process, in step (iii), the pellicle layer consists essentially of a material selected from silica, fluorine doped silica, aluminum doped silica, methylated silica, fluorinated and methylated silica, fluorinated aluminum doped silica, CaF₂, MgF₂, BaF₂ and SiC.

Preferably, the pellicle layer in step (iii) of the process of the present invention is deposited via chemical vapor deposition, plasma vapor deposition or sol-gel processes. Preferably, the chemical vapor deposition and plasma vapor deposition processes are selected from plasma enhanced chemical vapor deposition (PECVD), low pressure chemical vapor deposition (LPCVD), sub-atmospheric chemical vapor deposition (SACVD), ion-assisted electron evaporation, non ion-assisted electron evaporation and sputtering. More preferably, the pellicle layer is deposited by using PECVD.

According to a preferred embodiment of the process of the present invention, the bonding between the pellicle layer and the pellicle mount frame in step (iv) is effected by wafer bonding. Such wafer bonding may be anodic bonding, low-temperature bonding and fusion-bonding, preferably anodic bonding. Preferably, the pellicle mount frame is made of a material having substantially the same thermal expansion coefficient as that of the pellicle layer. Preferably, the pellicle mount frame is porous and allows for the passage of the purging gas, if any, used in the lithographic process. Where the pellicle layer is silica or modified silica, the pellicle mount frame can be porous silica.

According to a preferred embodiment of the process of the present invention, after step (v), additional step (vi) or (vii) as follows is carried out:
(vi) removing the residual material from the ion-implanted layer on top of the first surface of the pellicle layer;
(vii) converting the residual material from the ion-implanted layer on top of the first surface of the pellicle layer to a material compatible with the pellicle layer.

Plasma etching is a preferred method in carrying out step (vi). Thermal oxidation is a preferred method for carrying out step (vii).

Preferably, after step (v) of the process of the present invention, optionally after step (vi) or (vii), an antireflective layer is formed on at least the pellicle layer surface opposite to the pellicle mount frame. Preferably, an antireflective coating is formed on both surfaces of the pellicle layer.

In a second aspect of the present invention, it is provided a hard pellicle comprising a pellicle layer having a first surface and a second surface, a thickness varying from about 5 to 120 μm, a high transmission and a high laser stability at the actinic wavelength of the photolithographic process in which the pellicle is to be used, and a pellicle mount frame attached to the peripheral area of the second surface of the pellicle layer. The pellicle mount frame is preferred to have substantially the same coefficient of thermal expansion of that of the pellicle layer. The hard pellicle of the present invention is particularly suitable for projection lithography at 157 nm and shorter wavelength where traditional polymer pellicles cannot be used. However, it is to be understood that the hard pellicle of the present invention may be employed in lithographic applications where longer wavelength of radiation, such as 193 nm or even longer, is used.

Preferably, the pellicle layer consists essentially of a material selected from silica, fluorine doped silica, aluminum doped silica, methylated silica, fluorinated and methylated silica, fluorinated aluminum doped silica, CaF₂, MgF₂, BaF₂ and SiC.

In a preferred embodiment of the pellicle of the present invention, where the pellicle layer is silica or modified silica, the pellicle mount frame is made of silica. Preferably, the pellicle mount frame is porous and allows for the passage of the purging gas, if any, used in the lithographic process.

In a preferred embodiment of the thin hard pellicle of the present invention, at least one surface of the pellicle layer is coated with an antireflective coating. This coating is typically located on the first surface, which is opposite to the pellicle mount frame. Where needed, the antireflective coatings can be applied to both the first and second surfaces of the pellicle layer.

Additional features and advantages of the invention will be set forth in the detailed description which follows, and in part will be readily apparent to those skilled in the art from the description or recognized by practicing the invention as described in the written description and claims hereof, as well as the appended drawing.

It is to be understood that the foregoing general description and the following detailed description are merely exemplary of the invention, and are intended to provide an overview or framework to understanding the nature and character of the invention as it is claimed.

The accompanying drawing is included to provide a further understanding of the invention, and is incorporated in and constitutes a part of this specification.

### BRIEF DESCRIPTION OF THE DRAWINGS

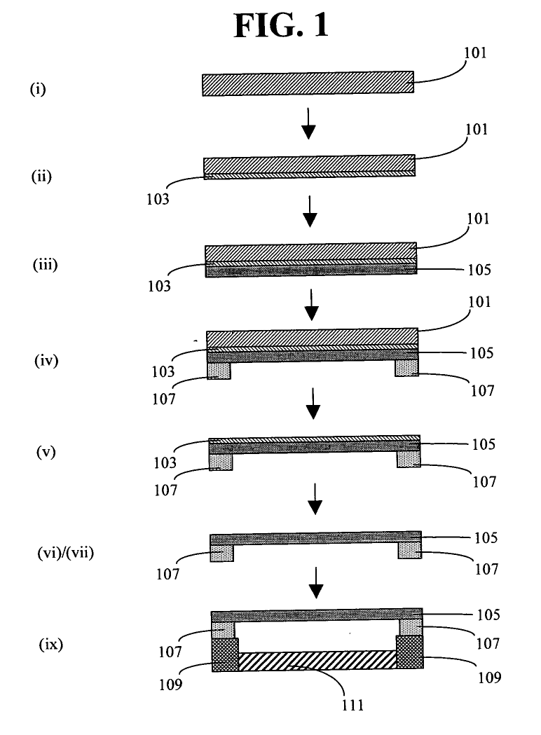

The accompanying drawing, FIG. 1, is a schematic illustration of the steps of a process of the present invention for making a thin hard pellicle having sub-mount frame and the mounting thereof to a reticle.

### DETAILED DESCRIPTION OF THE INVENTION

Pellicles serve as dust covers of reticles and protect the increasingly more expensive reticles from being contaminated in the lithographic process. Usually, a pellicle is an assembly comprising a thin pellicle layer mounted to a pellicle mount frame. Because the pellicle layer has a thin thickness compared to a relatively large surface area, the layer is sometimes called a membrane or a film. Typically, the pellicle layer has been made by stretching a thin (˜0.8 μm) polymer layer over an aluminum frame. As discussed above, this approach does not appear viable for 157 nm and shorter wavelength applications because the polymers rapidly degrade under the exposure of these wavelengths. An alternative was proposed by SEMATECH to use a hard pellicle comprised of silica or doped silica. Because silica has a higher modulus and density than polymer layers, initial efforts have focused on very thick (300-800 μm) silica plates to avoid sag, which causes wavefront distortion. The leading candidate material as of the end of 2002 has been an 800 μm thick silica pellicle manufactured by Asahi Glass, Japan. This is basically a reticle blank. Because of the large optical thickness of these hard pellicles, very tight specifications on absorption, flatness, bow, and wavefront distortion have been set by SEMATECH to minimize the impact on performance of the projection lithographic system.

The process proposed herein by the present inventor can be used for producing a thin hard pellicle comprising a pellicle layer having a thickness between 5-120 μm which overcomes many of the drawbacks of the thick hard pellicles. In general terms, the process of the present invention comprises forming the pellicle layer on a substrate, mounting the pellicle mount frame to the layer, followed by separation of the layer from the substrate. The steps of the process of the present invention are described in detail as follows with reference to FIG. 1.

In step (i) of the process of the present invention, a silicon wafer substrate 101 is provided. The wafer should have a substantially flat and smooth surface on which the pellicle layer will be deposited. Since the pellicle layer deposited on the substrate is quite thin, the roughness of the pellicle layer will depend on the roughness of the substrate surface. Thus advantageously the substrate surface on which the pellicle layer is to be deposited should have a flatness and roughness required for the pellicle layer. Nowadays, silicon wafers having a high quality surface can be produced in the semiconductor industry with relatively low cost. Thus the silicon wafers typically used for producing integrated circuit chips can be advantageously used for the present invention process. The size and shape of the silicon wafer substrate are not crucial. However, the substrate should have a size equal to or larger than that of the intended individual pellicle layer. It is contemplated that the substrate may have a large surface on which a layer for multiple pellicles can be deposited in a single deposition operation. The composition of the wafer is not crucial either, as long as an effective and efficient ion implantation and pellicle layer separation can be effected.

Step (ii) of the process of the present invention involves ion implantation into the wafer near the flat surface on which the pellicle layer is to be deposited. Ion implantation has been widely used in the semiconductor industry. Ion implantation involves the bombardment of solid material with medium-to-high energy ionized atoms. The ion travels through the surface to form a very thin near-surface layer which has unique properties different from that of the bulk of the solid material. The net penetration of the ion into the material, measured as projected onto the original trajectory, is called the projected range. Ion-implanted process is a random process, usually involves forming a Gaussian-shaped impurity depth profile whose centroid is defined as the average projected range. The statistic nature of the ion scattering process gives rise to a distribution of ions around the projected range depth. Accordingly, there exists a position having the peak ion concentration in the implanted layer. The ion energy directly affects both the range and the distribution of the implanted ions in a given substrate. Particularly relevant to the present invention are the ion implantation processes in forming silicon-on-insulator (SOI) materials by wafer bonding and Smartcut®. Hydrogen ion or proton implantation is typically used. Helium ion implantation can be used individually or in combination with hydrogen ion implantation. Fluorine ion implantation may be used as well. The ion dosage typically used for the Smartcut® process can be used for the present invention. For example, where hydrogen ion implantation is used, the typical dose is in the range from 2×10¹⁶ to 1×10¹⁷ ions/cm². As a result of the ion implantation, a buried implanted layer 103 adjacent to the surface of the wafer 101 through which the ion is implanted is formed. The energy of the ion implanted determines the depth of the buried implanted layer 103 under the surface. Whereas in the case of producing SOI using single crystalline silicon wafer, measures such as temperature control should be specifically taken in order to obtain a uniform and consistent split layer in a subsequent separation stage that is still single crystalline silicon, in the present invention, such conditions may not be necessarily required for the function of the pellicle layer, since the residual layer from the wafer substrate is not required, and indeed may be removed and converted, in subsequent steps. The main purpose of ion implantation in the process of the present invention is to enable the separation of the pellicle layer and a portion of the ion-implanted layer from the silicon wafer substrate in the subsequent step (v).

In step (iii), a pellicle layer 105 is deposited on the surface of wafer 101 through which the ion implantation has been carried out. This pellicle layer 105 will be separated in a subsequent step to form the pellicle membrane of a hard pellicle of the present invention. The pellicle layer consists essentially of a material selected from silica, fluorine doped silica, fluorine doped silica, aluminum doped silica, methylated silica, fluorinated and methylated silica, fluorinated aluminum doped silica, CaF₂, MgF₂, BaF₂ and SiC. The choice of the material is determined by the lithographic process. For example, in 157 projection lithographic processes, silica and doped silica can be used. At an even shorter wavelength where silica may not be transmissive or laser robust enough, materials such as CaF₂, MgF₂ and SiC may be employed advantageously. Generally, the thickness of the deposited pellicle layer is in the range from 5 to 120 μm, preferably 10 to 100 μm, more preferably 20 to 80 μm. Generally, a thicker film has a higher mechanical stability and thus facilitates handling. However, a thinner film causes wavefront distortion in the light path to a lesser degree. Usually, in photolithography at 157 nm and shorter wavelength, continuous purging of the reticle and pellicle system using a non-absorbing gas, typically N₂, is required. The oscillation of the pellicle layer caused by the flowing gas and ambient sources has been observed during the purging process. Such pellicle layer oscillation can cause variable wavefront distortion and thus interfere with the projection lithographic process. Typically, a thicker pellicle layer has a lesser oscillation amplitude. A thinner pellicle layer tends to have a higher oscillation amplitude under the same condition. Since a thinner pellicle layer does not constitute an optical element as significant as a thick layer, the more pronounced oscillation does not always entail a higher wavefront distortion. However, a layer less than 5 μm thick may not be able to withstand the oscillation and tends to break.

Deposition of the pellicle layer can be carried out using film-forming methods known in the art. For example, chemical vapor deposition (CVD) processes, such as plasma enhanced chemical vapor deposition (PECVD), low pressure chemical vapor deposition (LPCVD), sub-atmospheric chemical vapor deposition (SACVD); plasma vapor deposition (PVD) processes, such as ion-assisted electron beam evaporation, non ion-assisted electron beam evaporation and sputtering; as well as sol-gel processes, and the like, can be used.

Chemical vapor deposition (CVD) is a widely used materials-processing technology. A good reference book on CVD is Chemical Vapor Deposition (Eds. J-H Park et al.), Surface Engineering Series, Volume 2 (ASM International®, July 2001), the relevant portion of which is incorporated herein by reference. The majority of its applications involve applying solid thin-film coatings to surfaces. Stated simply, CVD involves flowing a precursor gas or gases into a chamber containing one or more heated objects to be coated. Chemical reactions occur on and near the hot surfaces, resulting in the deposition of a thin film on the surface. By-products along with unreacted precursor gases are exhausted out of the chamber. PECVD, LPCVD and SACVD are only a few variants of CVD techniques. CVD can be carried out at a wide range of temperature and pressure, with or without carrier gases. The majority of the elements in the periodic table have been deposited by CVD techniques, some in the form of the pure element, but more often combined to form compounds.

Among these CVD processes, PECVD is a preferred process for depositing the pellicle layer in the present invention. In a PECVD system, a RF source excited electrons in an electromagnetic field set up between a top electrode and a grounded substrate. The excited electrons collide with gas molecules to form ions/reactive neutrals or plasma. PECVD has several advantages over thermal CVD techniques. First, PECVD allows for a much lower deposition temperature and pressure. For example, the temperature for PECVD deposition of SiO₂ using SiH₄ and O₂ or N₂O is typically between 200-400° C., in contrast to the 350-550° C. temperature required for thermal CVD. Second, by using a plasma, ion bombardment aides in making films denser, increases deposition rate, and promotes good film adhesion. Moreover, film uniformity in terms of microstructure and thickness can be achieved. Still another great advantage of PECVD is its ability in controlling residual film stress. By varying process parameters, the user can create films with compressive or tensile stress or without stress. As a thin film, the pellicle layer deposited is preferred to be substantially stress free, so that upon separation from the substrate wafer at a later stage, it will not break or bow due to the internal stress.

The plasma vapor deposition techniques do not involve a chemical reaction between the wafer material and the material being deposited onto it. In the evaporation methods, the material to be deposited is heated in a vacuum, until it boils or sublimes to become a gas. The gas is transported to the substrate, where it is cooled and condenses onto the wafer substrate to form the deposited coating. In sputtering, the material to be deposited is literally thrown at the wafer substrate at a high velocity. A wide variety of sputtering techniques have been developed. Thin films of many materials, including silicon dioxide, have been deposited using evaporation or sputtering techniques.

Sol-gel process for thin film formation involves the coating of a sol-gel of the material being deposited onto the surface of the wafer substrate, followed by drying and heat treatment to form a dense interconnected film of the deposited material. In the case of silica, for example, a sol-gel material can be created by acidic hydrolysis of alkoxysilanes. The thus formed colloidal sol-gel is coated onto the substrate surface, dried and heat treated below 300° C. to form a dense coating. A higher temperature heat treatment may be used to sinter the film for a higher densification.

Whatever coating deposition process is used, it is important that the coating deposition process does not adversely affect the composition and property of the ion-implanted layer 103. For example, if the substrate is exposed to a high temperature, such as over 500° C., for a prolonged period of time, defects in the ion-implanted layer will be generated and the layer 103 may separate from the wafer substrate prematurely, and the film 105 as deposited will not adhere to the wafer substrate with sufficient strength to withstand the subsequent steps. In addition, as discussed supra, the deposited thin film is preferred to be substantially free of internal stress to have maximal mechanical stability and minimal bowing problem when separated from the silicon wafer to form into the pellicle layer. Furthermore, the deposited pellicle layer 105 should have a high transmission at the actinic wavelength of the lithographic tool. This requires the film to have a low OH concentration, for example, below 800 ppm for 157 nm applications. As discussed infra, tailoring of the composition of the pellicle layer, such as reduction of OH concentration in the pellicle layer, may be carried out at a later stage.

The thus deposited film 105 has two surfaces: a first surface bonding to the wafer surface on which the film is deposited, and a second surface which is opposite to the first surface and exposed. The second surface should advantageously have a high flatness and surface smoothness that meet the requirement of a pellicle layer. Parallelism of the second surface with respect to the first surface should be insured. Many film deposition processes mentioned above can produce films having a high overall flatness and a low center-line roughness. For example, the surface roughness of a PECVD deposited film can typically reach 2% of the film thickness, and even better if the process parameters are tightly controlled. However, where necessary, further polishing of the second surface may be conducted by using conventional polishing techniques, such as chemical-mechanical polishing as used in the semiconductor industry. In addition, the surface and composition of the pellicle layer can be further enhanced at a later stage of the process of the present invention, as discussed infra.

After the formation of film 105, an antireflective coating may be deposited using conventional methods as needed. The choice of the antireflective coating material, its structure (single layered or multiple layered, for example), and thickness depends on the application, in particular, the actinic wavelength of the lithographic tool. One skilled in the art can choose the proper antireflective coating and the coating technique to suit the needs of different applications and pellicle layers.

The next step, step (iv), of the process of the present invention for making a pellicle involves mounting the pellicle frame 107 to the second surface of the pellicle layer 105. The frame is mounted to the peripheral area of the second surface. Because of the presence of the wafer substrate 101, breakage of the pellicle layer 105 during mounting is not a significant concern. Thus mounting the frame to the pellicle layer is much easier than direct mounting to a discrete thin pellicle layer in the prior art. Various bonding techniques known in the art may be employed to bond the frame to the pellicle layer. For example, a low temperature frit may be used to weld the frame to the pellicle layer. A very thin layer of the frit can be deposited using thin film deposition methods described above onto the top surface of the frame to be bonded to the pellicle layer, or to the peripheral area of the pellicle layer to be bonded to the frame, or both. An exemplary frit useful for this bonding step is a B₂O₃—P₂O₅—SiO₂ glass composition consisting essentially of, by weight percent of the composition, about 20% B₂O₃, 4% P₂O₅ and the remainder SiO₂. Care should be taken that such film should have a very thin and even thickness, such that the pellicle layer will remain substantially flat and parallel to the reticle surface after being mounted to a reticle in a subsequent step. To reach this low-tilt goal, both the surface of pellicle layer 105 and the pellicle frame to be bonded together should be very flat and smooth. Chemical mechanical polishing again may be used to realize the required surface condition. Because of the relatively high processing temperature in the subsequent steps, polymer adhesives such as epoxy adhesives are not useable for mounting the frame to the pellicle layer in the process of the present invention.

Among the many bonding techniques available for mounting the frame to the pellicle layer 105, wafer bonding is preferred. Wafer bonding involves the direct bonding of two very flat, smooth and clean surfaces together without the use of adhesives. A high voltage electric field may be applied between the two surfaces being bonded to assist the bonding process in the so-called anodic bonding process. The presence of ions in the substrate and the mounting frame can contribute to successful anodic bonding. To that effect, Group I and II metals, such as Na, Li, K may be added into the mount frame and/or the peripheral area of the pellicle layer 105 by, for example, ion implantation, PVD and sol-gel processes described supra. The deposited ion can be present in a SiO₂—R₂O, SiO₂—R₂O—RO or SiO₂—RO system (where R denotes Group I or II metals). The bonding between the two surfaces may be effected with the presence of an intermediate film, such as water, at a low temperature in the low temperature bonding process. The intermediate layer may be dissipated in a later heat treatment. Alternatively, fusion bonding may be employed to fuse the surface of the pellicle mount frame and the second surface of the pellicle layer together at a high temperature. Fusion bonding is a direct bonding technique that does not need any intermediate layer. Bonding can be facilitated by imposing mechanical pressure between the two contacting surfaces. The key to successful wafer bonding is clean, smooth and flat surfaces. Particles between the two surfaces are detrimental to the bonding and therefore utmost care must be taken to avoid them. Also temperature differential is detrimental to an effective wafer bonding for anodic bonding and especially low temperature bonding. Therefore, when these two techniques are employed, temperature differential between the pellicle layer and the pellicle mount frame should be minimized.

The frame is pre-formed before mounting to the pellicle layer. Mismatch of coefficient of thermal expansion between the pellicle layer and the frame can cause bowing of the pellicle layer. Bowing causes undesirable wavefront distortion in the lithographic light path. The stress generated as a result of the bowing may lead to fracture of a thin pellicle layer as well. To minimize bowing, a frame having substantially the same coefficient of thermal expansion is preferred. The difference in linear coefficient of thermal expansion (CTE) of the frame material and the pellicle layer should be less than 2×10⁻⁶/° C., preferably less than 1×10⁻⁶/° C., more preferably less than 5×10⁻⁷/° C. Preferably, the frame is made of substantially the same material of the pellicle frame. For example, where the pellicle layer is silica or modified silica, such as aluminum doped silica, fluorine and aluminum doped silica, methylated silica, etc., the frame is advantageously made of silica as well. The frame should form an enclosure which, upon being mounted to a reticle, prevents dust particles from entering into the cavity defined by the pellicle and the reticle and contaminating the reticle.

Purging of the pellicle-reticle system is an important issue in lithography at 157 nm and shorter wavelength. Purging gas, such as purified N₂, is continuously flowing through the cavity to displace the absorbing oxygen. For soft pellicles having a gas-permeable polymer pellicle layer, purging is relatively easier because the pellicle membrane is the major area of mass transfer. Hard pellicle layers are generally not gas-permeable. Therefore, to facilitate purging, gas-permeable filters that block dust particles may be installed on the wall of the pellicle mount frame. However, a preferred approach is using a porous pellicle mount frame. The pores in the frame wall should allow for free passage of the purging gas but not the dust particles. By careful control of the initial glass composition, heat treatment, and chemical leaching, glass products having uniform interconnected (open) porosity can be made with a wide selection of pore sizes, for example, from 4 nm to 20 nm. These porous glasses are permeable for the purging gas, usually purified N₂. Another advantage of using porous glass pellicle frame involves the high internal surface area (up to about 300 m²/g), which is highly absorptive of ambient water. The surfaces of the pores may be chemically modified to increase its absorption capability of detrimental chemical species, such as water, O₂, etc. Thus the porous pellicle frame serves as a getter in the purging process as well. In a preferred embodiment, in particular where silica or modified silica mentioned supra constitutes the pellicle layer, the pellicle mount frame is made of porous silica. Porous silica is typically made by phase separating alkali borosilicate glass, chemically leaching out the non-silica phase and consolidating to a fully dense body, consisting essentially of approximately 96 wt % of SiO₂, 3 wt % of B₂O₃ and less than 0.5 wt % of alkali oxides. It is consolidated by firing in vacuum at about 1200° C. An example of such porous silica is Vycor® glass, such as Corning code 7900 glass.

The next step of the process of the present invention for making a photomask pellicle involves the separation of the deposited pellicle layer 105 from the wafer substrate 101. It is known that by proper annealing, H, He or F ion implanted silicon layer can be separated from a silicon wafer. Without intending to be bound by any particular theory, it is believed that defects form in the implanted layer as a result of the ion implantation. Such defects grow larger upon annealing and eventually lead to the separation of the ion-implanted layer from the wafer substrate. Such splitting usually takes place at the peak location of the implanted ion. This process has found application in the production of SOI structures. Typically, a low temperature annealing at 400-600° C. can lead to the splitting of the ion-implanted layer of silicon from a silicon wafer at the position of hydrogen peak in the wafer near the wafer surface, if the wafer surface is properly bonded to another receiving silicon wafer via wafer bonding. The split thin silicon layer remains bonded to the surface of the receiving silicon wafer. The annealing temperature is also conducive to strengthening the wafer bonding between the receiving wafer and the split thin silicon film. The pellicle fabrication process of the present invention takes advantage of the splitting-capable property of the ion-implanted layer. By proper heat treatment, the deposited layer splits from the surface of the wafer substrate on which it is formed at the position of the peak of implanted ions. As a result, a pellicle layer 105 bonded to a mounting frame 107 on its second surface is generated. The pellicle layer thus separated from the silicon wafer has a thin silicon layer on its first surface split from the ion-implanted layer 103. In this way, the process of the present invention avoids mounting the pellicle frame to a discrete thin film directly and the possibility of fracture associated with such direct mounting. The wafer substrate 101 may be recycled for making the next pellicle upon separation. Surface finishing by chemical mechanical polishing may be used before it is being used again.

The separation step (v) may be carried out simultaneously with the pellicle frame mounting step (iv). This scheme is especially applicable in the following situations, among others: (a) where high temperature fusion bonding is employed to effect the bonding between the pellicle layer 105 and the pellicle mount frame 107 in step (iv); and (b) where a frit is used to bond the pellicle mount frame 107 and the pellicle layer 105 in step (iv), which requires a processing temperature that typically may lead to the splitting of the ion implanted layer from the wafer substrate.

In the ion-implantation, wafer bonding and thermal splitting process for making SOI wafers in the semiconductor sector (the so-called Smartcut® process), the annealing temperature is necessarily carefully controlled such that a uniform single-crystalline silicon layer splits from the donating wafer while remaining sufficiently bonded to the receiving wafer. The quality of the split silicon thin layer is of importance to the SOI wafer. In the process of the present invention, such residual thin layer from the donating wafer is not required for the function of the pellicle layer in a hard pellicle assembly. Therefore, the processing temperature requirements for step (v) and/or (vi) are not necessarily as stringent as that of the SOI Smartcut® process. As long as the temperatures and other process conditions can effect a successful splitting of the pellicle layer from the donating wafer substrate, and a strong bonding between the pellicle mount frame and the pellicle layer, they are acceptable. A higher processing temperature within the acceptable range may be conducive to the formation of a strong bond between the pellicle frame and the pellicle layer, as well as a smooth surface of the pellicle layer. Thus, for the process of the present invention, the thermal treatment temperature in step (v) can be in the range from about 300-800° C., preferably from 350-700° C., more preferably from 400 to 600° C. The thermal treatment time in step (v) can be chosen to be suitable for the temperature.

The assembly consisting of the split pellicle layer 105, the pellicle mount frame 107, and a thin layer 103 from the donating wafer substrate, may be used directly as a pellicle system for mounting on a reticle, or may be subjected to further processing steps where necessary. For example, if the pellicle layer has been split from the wafer substrate in step (v) at a low temperature such as 400-600° C., an additional heat treatment at a higher temperature, such as 800° C., may be desired to strengthen the bonding between the pellicle frame and the pellicle surface, and to further enhance the surface roughness of the pellicle layer. In addition, in order to enhance the composition of the pellicle layer, the pellicle layer-mount frame system may be subjected to heat treatment in H₂ or He atmosphere, to reduce the OH concentration where necessary. Another treatment, used independently or in conjunction with the above treatment, involves the following step (vi) or (vii):
(vi) removing the residual material from the ion-implanted layer on top of the first surface of the pellicle layer;
(vii) converting the residual material from the ion-implanted layer on top of the first surface of the pellicle layer to a material compatible with the pellicle layer.

The thin layer 103 on top of the first surface of the pellicle layer 107, which is silicon, is not required for the function of the pellicle layer in a lithographic process. Indeed the presence of silicon on top of the pellicle layer is detrimental for the transmission of 157 nm and shorter wavelength. Thus, such silicon layer should be removed or converted to a layer compatible with the pellicle layer. “A layer compatible with the pellicle layer” means a layer that does not interfere with or negatively affect the function of the pellicle layer, for example, transmission of the lithographic radiation. A layer compatible with the pellicle layer may have the same or different chemical composition of the pellicle layer. Indeed, upon such conversion, the resulting layer compatible with the pellicle layer becomes an integral part of the pellicle layer of the hard pellicle system of the present invention. Plasma etching can be advantageously used for removal of the silicon layer. The etchant and etching condition can be chosen such that selective etching of the silicon layer can be effected without removing the deposited pellicle layer 105 or the pellicle frame 107. Thermal oxidation can be used to convert the silicon layer to silica if silica is compatible with the pellicle layer, for example, where the deposited layer is a silica layer as well. This thin ion implanted layer removal or conversion may be performed immediately after step (v), in conjunction with the heat treatment mentioned above for strengthening the frame to pellicle layer bonding. The heat treatment in H₂/He atmosphere mentioned above may be advantageously carried out after the steps (vi) or (vii).

The thus obtained hard pellicle assembly comprising a thin pellicle layer and an integrated pellicle mount frame should have good pellicle layer surface flatness and smoothness. Of course, where necessary, further surface polishing step can be undertaken. After all these steps, a surface antireflective layer can be coated on at least one of the two surfaces of the pellicle layer. As described supra, the antireflective coating on the second surface may have been deposited in a previous step. If this is the case, then only the top surface, which may be the first surface of the pellicle layer, or the surface of the layer compatible with the pellicle layer obtained from step (vii), needs to be coated with the antireflective coating. Methods known in the art, such as the CVD and PVD processes described supra can be employed to form the antireflective coating or coatings. The composition and structure (single or multiple layered) of the coatings depend on the specific application, in particular, the actinic wavelength of the lithographic process. During this coating process, the pellicle system may be subjected to further heat treatment, which further enhances the adhesion of the pellicle layer to the pellicle mount frame. The finished pellicle system can then be packaged and shipped to the lithographer.

The lithographer mounts the pellicle system on top of the reticle as illustrated in step (ix) in FIG. 1. The pellicle mount frame 107 can be placed on top of a reticle directly. Alternatively, as shown in step (ix) of FIG. 1, the reticle has a submount 109 itself, on which the pellicle mount frame 107 is placed. This sub-mount on sub-mount structure is preferred, since replacement of damaged pellicle is easier.

The thin hard pellicle of the present invention is advantageously produced using the method of the present invention. The attributes of the pellicle of the present invention can be understood by reference to the above description of the process.

The hard pellicle of the present invention comprises a hard pellicle layer having a first surface and a second surface, a thickness varying from about 5 to 120 μm, and a pellicle mount frame attached to the peripheral area of the second surface of the pellicle layer. The hard pellicle layer can be made of a material consisting essentially of a material selected from, inter alia, silica, fluorine doped silica, aluminum doped silica, methylated silica, fluorinated and methylated silica, fluorinated aluminum doped silica, CaF₂, MgF₂, BaF₂ and SiC. Advantageously, the pellicle mount frame is made of a porous material that allows for the free passage of the purging gas but not the dust particles. The porous material can be advantageously made of Vycor® glass. The pellicle layer can be coated with antireflective coating on one or both sides.

The hard pellicle of the present invention is particularly good for projection photolithography in the vacuum ultraviolet range, such as 157 nm and shorter wavelength where traditional polymer pellicle membrane cannot be used. However, where necessary, the pellicle of the present invention can also be used for lithographic processes at longer wavelength, such as 193 μm or 248 nm.

Because the pellicle layer of the hard pellicle of the present invention has a thickness in the range from about 5-120 μm, it does not function as a significant optical element in the light path of the lithographic application. Thus, distortion caused by the pellicle layer is reduced compared to 800 nm hard pellicle. Concerns on tilt and uniformity of the pellicle layer are not as significant as on thick hard pellicles. Meanwhile, pellicle layers having high surface uniformity can be produced by using the process of the present invention as described supra. Inspection of the reticle while using the pellicle of the present invention thus also becomes easier. By choosing the proper material for the pellicle layer, the pellicle can have the excellent laser durability and transmission such as those of the photomask blank at the actinic wavelength of the photolithographic process. For example, the pellicle layer can have at least 85%, preferably at least 90%, more preferably at least 95% initial transmission at the actinic wavelength, such as 157 nm.

It will be apparent to those skilled in the art that various modifications and alterations can be made to the present invention without departing from the scope and spirit of the invention. Thus, it is intended that the present invention cover the modifications and variations of this invention provided they come within the scope of the appended claims and their equivalents.

1. A pocess for making a hard pellicle for a photomask, comprising the following steps:
(i) providing a silicon wafer having a substantially flat surface;
(ii) forming an ion-implanted layer adjacent to the flat surface of the silicon wafer;
(iii) depositing a pellicle layer having a first surface and a second surface on the surface of the ion-implanted layer, with the first surface bonding to the surface of the ion-implanted layer, and the second surface opposite to the first surface;
(iv) bonding a pellicle mount frame to the second surface of the pellicle layer; and
(v) separating the pellicle layer and a portion of the ion-implanted layer from the silicon wafer at a location within the ion-implanted layer by heat treatment.

2. A process in accordance with claim 1, wherein in step (ii), the ion-implanted layer is formed by hydrogen, helium and/or fluorine ion implantation, and the separation in step (v) is carried out by thermal annealing.

3. A process in accordance with claim 1, wherein in step (iii), the pellicle layer consists essentially of a material selected from silica, fluorine doped silica, aluminum doped silica, methylated silica, fluorinated and methylated silica, fluorinated aluminum doped silica, CaF₂, MgF₂, BaF₂ and SiC.

4. A process in accordance with claim 1, wherein in step (iii), the pellicle layer is deposited via chemical vapor deposition and/or plasma vapor deposition, or sol-gel process.

5. A process in accordance with claim 4, wherein in step (iii), the pellicle layer is deposited via a process selected from plasma enhanced chemical vapor deposition (PECVD), low pressure chemical vapor deposition (LPCVD), sub-atmospheric chemical vapor deposition (SACVD), ion-assisted e-beam evaporation, non ion-assisted e-beam evaporation and sputtering.

6. A process in accordance with claim 4, wherein in step (iii), the pellicle layer is deposited via plasma enhanced chemical vapor deposition (PECVD).

7. A process in accordance with claim 1, wherein in step (iv), the bonding between the pellicle layer and the pellicle mount frame is effected by wafer bonding.

8. A process in accordance with claim 7, wherein the bonding is effected by anodic bonding, low-temperature bonding or fusion bonding.

9. A process in accordance with claim 1, wherein in step (iv), the bonding between the pellicle layer and the pellicle mount frame is effected by using frit.

10. A process in accordance with claim 1, wherein in step (iv), the pellicle mount frame consists essentially of a material having substantially the same coefficient of thermal expansion as that of the pellicle layer.

11. A process in accordance with claim 1, wherein in step (iv), the pellicle mount frame consists essentially of silica.

12. A process in accordance with claim 10, wherein the pellicle mount frame is porous and allows for the passage of purging gas used during the lithographic process.

13. A process in accordance with claim 1, further comprising either a further step (vi) as follows:
(vi) removing the residual silicon material from the ion-implanted layer on top of the first surface of the pellicle layer;
or a step (vii) as follows:
(vii) converting the residual silicon material from the ion-implanted layer on top of the first surface of the pellicle layer to a material compatible with the pellicle layer.

14. A process in accordance with claim 13, wherein step (vi) is carried out, and plasma etching is used to remove the residual silicon.

15. A process in accordance with claim 13, wherein step (vii) is carried out, and thermal oxidation is used to convert the residual silicon to silica.

16. A process in accordance with claim 1, further comprising the following step (viii) after step (v):
(viii) forming an antireflective coating on at least the pellicle surface opposite to the pellicle mount frame.

17. A process in accordance with claim 13, further comprising the following step (viii) after step (vi) or (vii):
(viii) forming an antireflective coating on at least the pellicle surface opposite to the pellicle mount frame.

18. A hard pellicle comprising a hard pellicle layer having a first surface and a second surface, a thickness ranging from about 5-120 μm, a high transmission and a high laser stability at the lithographic wavelength, and a pellicle mount frame attached to the peripheral area of the second surface of the pellicle layer.

19. A hard pellicle in accordance with claim 18, wherein the pellicle mount frame has substantially the same coefficient of thermal expansion of that of the pellicle layer.

20. A hard pellicle in accordance with claim 18, wherein the pellicle layer consists essentially of a material selected from silica, fluorine doped silica, aluminum doped silica, methylated silica, fluorinated and methylated silica, fluorinated aluminum doped silica, CaF₂, MgF₂, BaF₂ and SiC.

21. A hard pellicle in accordance with claim 18, wherein the pellicle mount frame is porous and allows for the passage of the purging gas used during the lithographic process.

22. A hard pellicle in accordance with claim 21, wherein the pellicle mount frame consists essentially of porous silica.

23. A hard pellicle in accordance with claim 19, wherein at least one surface of the pellicle layer is coated with an antireflective coating.
